(19) United States
(12) Patent Application Publication
(10) Pub. No.: US 2026/0040881 A1
(43) Pub. Date: Feb. 5, 2026

(54) THERMAL MANAGEMENT IN SUBSTRATE SUPPORTS

(71) Applicant: Applied Materials, Inc., Santa Clara, CA (US)

(72) Inventors: Arvinder Manmohan Singh Chadha, San Jose, CA (US); Syed Nazmul Ahsan, Fremont, CA (US)

(21) Appl. No.: 18/791,043

(22) Filed: Jul. 31, 2024

(51) Int. Cl. H01L 21/683; H05B 3/00; H05B 3/28

(52) U.S. Cl. CPC H01L 21/6833; H05B 3/0019; H05B 3/283; H05B 2203/002; H05B 2203/014; H05B 2203/016; H05B 2213/07

(57) ABSTRACT

A system, including a ceramic base and a resistive heating trace embedded in the ceramic base. The resistive heating trace includes a plurality of elongated parallel trace segments, where each trace segment extends across a major surface of the ceramic base. The resistive heating trace further includes a first terminal coupled to a first elongated parallel trace segment of the plurality of elongated parallel trace segments and disposed a first radial distance from a center of the ceramic base. The resistive heating trace further includes a second terminal coupled to a second elongated parallel trace segment of the plurality of elongated parallel trace segments and disposed a second radial distance from the center of the ceramic base.

### TECHNICAL FIELD

The present disclosure generally relates to systems and methods for thermal management in substrate supports. More particularly, the present disclosure relates to systems and methods for thermal management in substrate support systems of semiconductor manufacturing systems.

### BACKGROUND

Semiconductor manufacturing processes can involve the use of substrate support systems (e.g., electrostatic chucks, heaters, vacuum chucks, etc.) to secure and handle substrates such as semiconductor wafers through fabrication stages. The thermal performance of substrate support systems can influence the performance of substrate manufacturing systems as well as the quality and reliability of the manufactured semiconductor devices.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the disclosure, a system includes a ceramic base and a resistive heating trace embedded in the ceramic base. The resistive heating trace includes a plurality of elongated parallel trace segments, wherein each trace segment extends across a major surface of the ceramic base. The resistive heating trace further includes a first terminal coupled to a first elongated parallel trace segment of the plurality of elongated parallel trace segments and disposed a first radial distance from a center of the ceramic base. The resistive heating trace further includes a second terminal coupled to a second elongated parallel trace segment of the plurality of elongated parallel trace segments and disposed a second radial distance from the center of the ceramic base.

In another aspect of the disclosure, a method includes identifying a ceramic base of an electrostatic chuck (ESC). The method further includes causing a resistive heating trace to be printed onto the ceramic base of the ESC. The resistive heating trace includes a plurality of elongated parallel trace segments, wherein each trace segment extends across a major surface of the ceramic base. The resistive heating trace further includes a first terminal coupled to a first elongated parallel trace segment of the plurality of elongated parallel trace segments and disposed a first radial distance from a center of the ceramic base. The resistive heating trace further includes a second terminal coupled to a second elongated parallel trace segment of the plurality of elongated parallel trace segments and disposed a second radial distance from the center of the ceramic base.

In another aspect of the disclosure, an apparatus includes a ceramic base and a resistive heating trace embedded in the ceramic base. The resistive heating trace includes a plurality of elongated parallel trace segments. The resistive heating trace further includes a first terminal coupled to a first elongated parallel trace segment of the plurality of elongated parallel trace segments. The resistive heating trace further includes a second terminal coupled to a second elongated parallel trace segment of the plurality of elongated parallel trace segments. The resistive heating trace further includes a plurality of bridging segments that adjoin adjacent elongated parallel trace segments of the plurality of elongated parallel trace segments, wherein at least one elongated trace segment of the plurality of elongated trace segments or at least one bridging segment of the plurality of bridging segments is disposed between the first terminal and the second terminal.

### BRIEF DESCRIPTION OF THE DRAWINGS

The present disclosure is illustrated by way of example, and not by way of limitation in the figures of the accompanying drawings.

FIG. 1 depicts a sectional side view of a processing chamber, according to some embodiments.

FIGS. 2A-B illustrate ceramic bases including resistive heating traces embedded in the ceramic bases, according to some embodiments.

FIGS. 3A-B illustrate modifying a surface profile of a component of a ceramic stack based on an updated surface profile, according to some embodiments.

FIGS. 4A-B are flow diagrams of methods associated with thermal management in substrate supports, according to some embodiments.

FIG. 5 is a block diagram illustrating an example system architecture, according to certain embodiments.

FIG. 6 is a block diagram illustrating a computer system, according to some embodiments.

### DETAILED DESCRIPTION

In the field of semiconductor manufacturing, controlling substrate temperature during processing can help to ensure the quality and integrity of manufactured electronic devices. Substrate supports such as electrostatic chucks (ESCs) are commonly used in various semiconductor fabrication processes such as etching, chemical vapor deposition (CVD), and physical vapor deposition (PVD) to securely hold and release semiconductor wafers. Controlling substrate temperature during processing can be affected by the temperature uniformity of a substrate support system. Conventional substrate support system designs often struggle with maintaining uniform temperature distribution across surface surfaces of the substrate support system, leading to potential defects in manufactured semiconductor devices.

Conventionally, substrate support systems such as ESCs include a ceramic base with embedded heating traces. Each heating trace has two terminals that are typically placed adjacent to each other and equidistant from a center of the ceramic base. However, this configuration can lead to significant temperature non-uniformities, particularly manifesting as cold spots between the terminals where the lack of direct heating reduces thermal coverage.

Further complicating temperature management in ESCs, the manufacturing process for embedding heater traces into the ceramic substrates of the ESCs introduces additional nonuniformities. For example, the traces can be printed onto the ceramic using techniques that allow for variation in trace width to tune the thermal profile across the ESC. However, inconsistencies in trace width and density often arise from the printing process. These imperfections are typically not evident in the initial modeling and can significantly degrade the ESC's thermal uniformity.

The challenge of achieving uniform temperature distribution is particularly exacerbated when the ceramic stack of the ESC is made thinner, a design choice often employed in applications requiring reduced mass and faster thermal response times, such as in rapid thermal processing (RTP) and certain advanced etching systems. Thinner ceramic stacks, while beneficial for these applications, are more susceptible to thermal non-uniformities due to their reduced thermal mass and increased thermal response speed.

These thermal inconsistencies are problematic as they can lead to areas of both overheating and underheating, which are detrimental to processes that require precise temperature control, such as lithography and etching. The effects of these temperature irregularities can include defects in the semiconductor wafers being processed, impacting yield and device reliability.

Additionally, the presence of non-uniform temperatures across the surface of the ESC complicates the effective application of electrostatic clamping force. Inadequate temperature control can disrupt the distribution of this force, leading to substrate slippage or misalignment during critical processing steps. Over time, this can exacerbate wear and degradation of the ESC, further diminishing its performance and operational lifespan.

Aspects and implementations of the present disclosure address these and other deficiencies of the existing technology by implementing a system that includes a resistive heating trace embedded within a ceramic base of a substrate support and two terminals placed at different radial distances from a center of the ceramic base. For example, a ceramic base of a ceramic stack of a substrate support such as an ESC can include a heating trace that has multiple elongated parallel traces spread across its surface. The resistive heating element includes two terminals each coupled to one of the elongated parallel traces. Each of the two terminals are disposed at a different radial distance from the center of the substrate, helping to eliminate cold spots between the two terminals. In some embodiments, bridging segments can be strategically positioned for enhanced thermal distribution uniformity. For example, bridging segments can connect adjacent elongated parallel trace segments and can be disposed between the first and second terminals, further helping to eliminate cold spots and enhancing temperature distribution uniformity.

In some embodiments, the first terminal is disposed on a first horizontal plane and the second terminal is disposed on a second horizontal plane. The first terminal, which is disposed on the first plane, is coupled to the second terminal, which is disposed on the second plane, through a via (e.g., a vertical via). In some embodiments, one of the terminals (e.g., the first terminal on the first plane) may be coupled to the via, which is coupled to a bus bar, with the bus bar being coupled to the other terminal (e.g., the second terminal on the second plane). The via can be made of a conductive metal material or any other suitable material for coupling the terminals and elongated parallel trace segments. In some embodiments, the first elongated parallel trace segment, which is coupled to the first terminal on the first plane, may be coupled to the second elongated parallel trace segment, which is coupled to the second terminal on the second plane, in series or parallel through the via.

In some embodiments, a ceramic base may include two or more sets of terminals corresponding to additional sets of elongated parallel trace segments. Each set of terminals corresponding to a set of elongated parallel trace segments can be coupled to the set of elongated parallel trace segments in series or parallel through a via. For example, a ceramic base having three sets of terminals corresponding to three additional sets of elongated parallel trace segments may include a first set of terminals corresponding to a set of elongated parallel trace segments that are coupled to the set of elongated parallel trace segments in series through a via, a second set of terminals corresponding to a set of elongated parallel trace segments that are coupled to the set of elongated parallel trace segments in parallel through a via, and a third set of terminals corresponding to a set of elongated parallel trace segments that are coupled to the set of elongated parallel trace segments in series through a via. For any number of sets of terminals corresponding to a set of elongated parallel trace segments, each set of elongated parallel trace segments can be coupled to the terminals in series or parallel through a via.

In some embodiments, a third horizontal plane, a fourth horizontal plane, a fifth horizontal plane, a sixth horizontal plane, and so on, may be disposed between the first horizontal plane and the second horizontal plane. A third elongated parallel trace segment, a fourth elongated parallel trace segment, a fifth elongated parallel trace segment, a sixth elongated parallel trace segment, and so on, may be disposed on each of the third horizontal plane, the fourth horizontal plane, the fifth horizontal plane, the sixth horizontal plane, and so on. In some embodiments, each of the additional horizontal planes disposed between the first horizontal plane and the second horizontal plane may include portions of the first elongated parallel trace segment and/or second elongated parallel trace segment. Any number of horizontal planes (e.g., 10-15 horizontal planes) may be included and any number of elongated parallel trace segments may extend across major surfaces of the horizontal planes. Any number of bridging segments may be included to adjoin adjacent elongated parallel trace segments.

In some embodiments, the system can include a memory and a processing device. The processing device can perform physics-based optimization (e.g., using a physics-based optimization model) by determining thermal uniformity data of the ceramic stack and determining an updated surface profile for a component of the ceramic stack. In some embodiments, the processing device can cause a surface profile of a component of the ceramic stack to be modified based on an updated surface profile (e.g., by laser material processing).

Aspects and implementations of the present disclosure can improve temperature uniformity across substrate supports by reducing cold spots between the terminals. Aspects and implementations of the present disclosure can further improve temperature uniformity across substrate supports by modifying surface profiles of components of the ceramic stack (e.g., of substrate support system such as an ESC). By modifying surface profiles of components of the ceramic stack, defects and nonuniformities from the manufacturing process for embedding heater traces into a ceramic base can be corrected.

Aspects and implementations of the present disclosure can reduce thermal non-uniformities in ceramic stacks of substrate support systems. This improvement is particularly significant in thinner ceramic stacks, which are often used in applications that require lower mass and quicker thermal response times. Due to their reduced thermal mass and faster response to temperature changes, these thinner stacks are typically more prone to thermal non-uniformities. Aspects and implementations of the present disclosure can eliminate areas of both overheating and underheating, decreasing defects in the semiconductor wafers being processed and increasing yield and device reliability. Aspects and implementations of the present disclosure can eliminate disruption of the electrostatic clamping force of an ESC, leading to increase substrate security and alignment during critical processing steps.

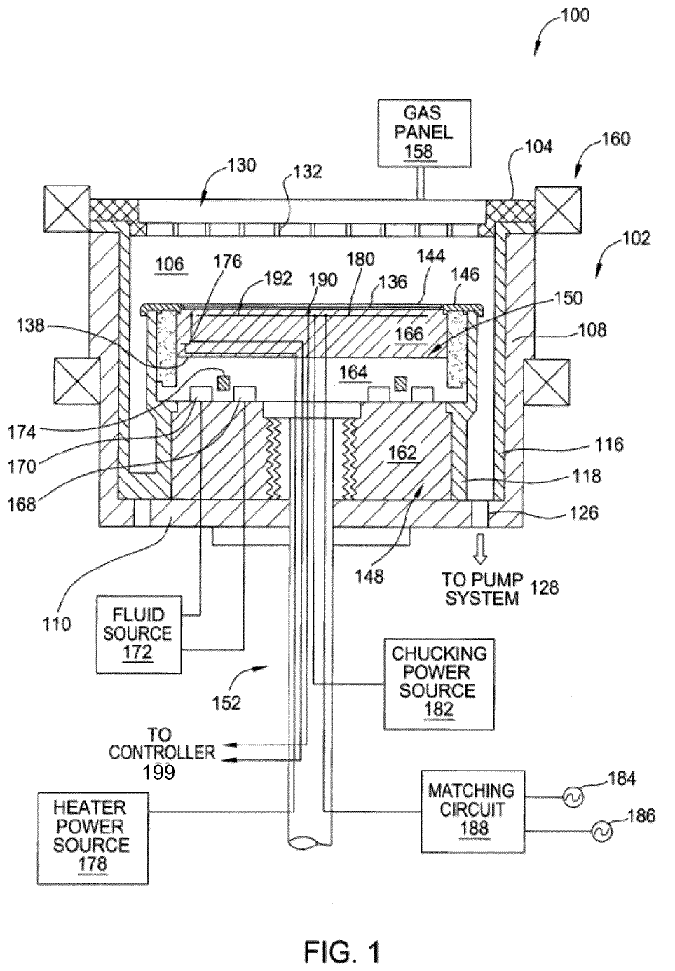

FIG. 1 depicts a sectional side view of a processing chamber 100 having an electrostatic chuck assembly 150 disposed therein, according to some embodiments. The electrostatic chuck assembly 150 includes an ceramic stack 166, as will be discussed in greater detail below.

The processing chamber 100 includes a chamber body 102 and a lid 104 that enclose an interior volume 106. The chamber body 102 may be fabricated from aluminum, stainless steel or other suitable material. The chamber body 102 includes sidewalls 108 and a bottom 110. An outer liner 116 may be disposed adjacent the sidewalls 108 to protect the chamber body 102. The outer liner 116 may be fabricated and/or coated with a plasma or halogen-containing gas resistant material. In one embodiment, the outer liner 116 is fabricated from aluminum oxide. In another embodiment, the outer liner 116 is fabricated from or coated with yttria, yttrium alloy or an oxide thereof.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The lid 104 may be supported on the sidewall 108 of the chamber body 102. The lid 104 may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through a gas distribution assembly 130 that is part of the lid 104. The gas distribution assembly 130 may have multiple apertures 132 on the downstream surface of the gas distribution assembly 130 to direct the gas flow to the surface of the substrate 144. Additionally, or alternatively, the gas distribution assembly 130 can have a center hole where gases are fed through a ceramic gas nozzle. The gas distribution assembly 130 may be fabricated and/or coated by a ceramic material, such as silicon carbide, Yttrium oxide, etc. to provide resistance to halogen-containing chemistries to prevent the gas distribution assembly 130 from corrosion.

A substrate support assembly 148 may be disposed in the interior volume 106 of the processing chamber 100 below the gas distribution assembly 130. The substrate support assembly 148 can hold a substrate 144 during processing. An inner liner 118 may be coated on the periphery of the substrate support assembly 148. The inner liner 118 may be a halogen-containing gas resist material such as those discussed with reference to the outer liner 116. In one embodiment, the inner liner 118 may be fabricated from the same materials of the outer liner 116.

In one embodiment, the substrate support assembly 148 includes a mounting plate 162 supporting a pedestal 152, and electrostatic chuck assembly 150. In one embodiment, the electrostatic chuck assembly 150 further includes a thermally conductive base referred to herein as a cooling plate 164 coupled to an electrostatic ceramic stack (referred to hereinafter as a ceramic stack 166). In some embodiments, the cooling plate 164 can be considered a component of the ceramic stack. The electrostatic chuck assembly 150 described in embodiments may be used for Johnsen-Rahbek and/or Coulombic electrostatic chucking.

In some embodiments, ceramic stack 166 of an electrostatic chuck (ESC) includes multiple integrated layers designed to facilitate effective substrate handling and heating during semiconductor processing. For example, ceramic stack 166 can include a clamp ceramic, which serves as the primary substrate contact surface, providing mechanical stability and electrostatic clamping capabilities for substrate support. Ceramic stack 166 can include a bond layer to enhance structural integrity and thermal conductivity. In some embodiments, the bond layer can be a metal bond layer that securely adheres the clamp ceramic to an underlying heater ceramic 166. A heater ceramic can incorporate a resistive heating trace embedded within a ceramic base. Ceramic stack 166 can include cooling plate 164.

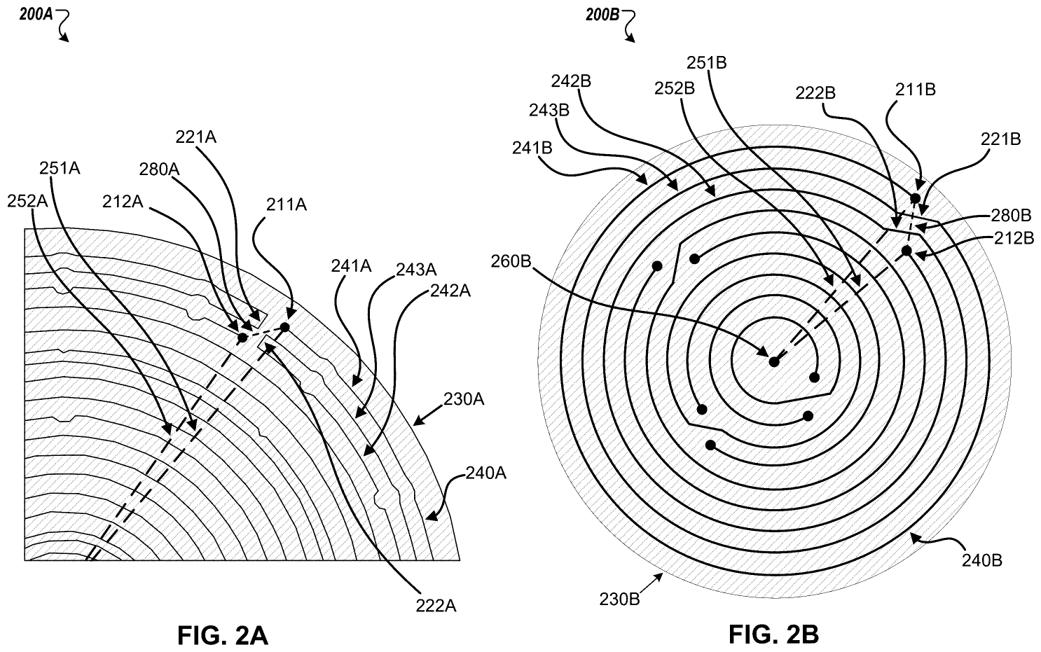

In some embodiments, the resistive heating trace embedded within the ceramic base includes two terminals placed at different radial distances from a center of the ceramic base. For example, the ceramic base of the ceramic stack 166 of a substrate support assembly 148 can include a heating trace that has multiple elongated parallel traces spread across a surface of the ceramic base. The resistive heating element can include two terminals each coupled to one of the elongated parallel traces. Each of the two terminals are disposed at a different radial distance from a center of the ceramic base. A more detailed description of some embodiments of the resistive heating trace is provided below in conjunction with FIGS. 2A-B.

In one embodiment, a protective ring 146, which may be referred to as a process kit ring, is disposed over a portion of the ceramic stack 166 and/or at an outer perimeter of the ceramic stack 166. In one embodiment, components of the ceramic stack 166 (e.g., the clamp ceramic layer) is coated with a protective layer 136. Alternatively, components of ceramic stack 166 may not be coated by a protective layer 136. The protective layer 136 may be a ceramic such as Y₂O₃ (yttria or yttrium oxide), Y₄Al₂O₉ (YAM), Al₂O₃ (alumina), Y₃Al₅O1₂ (YAG), YAlO₃ (YAP), Quartz, SiC (silicon carbide), Si₃N₄ (silicon nitride) Sialon, AlN (aluminum nitride), AlON (aluminum oxynitride), TiO₂ (titania), ZrO₂ (zirconia), TiC (titanium carbide), ZrC (zirconium carbide), TiN (titanium nitride), TiCN (titanium carbon nitride), Y₂O₃ stabilized ZrO₂ (YSZ), and so on. The protective layer may also be a ceramic composite such as Y₃Al₅O1₂ distributed in Al₂O₃ matrix, Y₂O₃—ZrO₂ solid solution or a SiC—Si₃N₄ solid solution. The protective layer may also be a ceramic composite that includes a yttrium oxide (also known as yttria and Y₂O₃) containing solid solution. For example, the protective layer may be a ceramic composite that is composed of a compound Y₄Al₂O₉(YAM) and a solid solution Y₂-xZrxO₃ (Y₂O₃—ZrO₂ solid solution). Note that pure yttrium oxide as well as yttrium oxide containing solid solutions may be doped with one or more of ZrO₂, Al₂O₃, SiO₂, B₂O₃, Er₂O₃, Nd₂O₃, Nb₂O₅, CeO₂, Sm₂O₃, Yb₂O₃, or other oxides. Also note that pure Aluminum Nitride as well as doped Aluminum Nitride with one or more of ZrO₂, Al₂O₃, SiO₂, B₂O₃, Er₂O₃, Nd₂O₃, Nb₂O₅, CeO₂, Sm₂O₃, Yb₂O₃, or other oxides may be used. Alternatively, the protective layer may be sapphire or MgAlON.

As described herein the ceramic stack 166 may include a single ceramic plate or multiple ceramic plates (e.g., clamp ceramic, a heater ceramic, cooling plate 164, etc.). For example, the ceramic stack 166 may include a clamp ceramic layer (e.g., a clamp ceramic) (not shown), a heater ceramic layer (e.g., a heater ceramic) (not shown), and the cooling plate 164. Each of the clamp ceramic layer, heater ceramic layer, and the cooling plate 164 can be bonded together by a metal bond, a diffusion bond, an organic bond, and/or other type of bond. The ceramic plates may be a dielectric or electrically insulative material (e.g., having an electrical resistivity of greater than 10¹⁴ Ohm·meter) that is usable for semiconductor processes at temperatures of 180° C. and above. In one embodiment, the ceramic plates are composed of materials usable from about 20° C. to about 500° C. In one embodiment, the ceramic plates are AlN. An AlN ceramic plate may be undoped or may be doped. For example, the AlN may be doped with Samarium oxide (Sm₂O₃), Cerium oxide (CeO₂), Titanium dioxide (TiO₂), or a transition metal oxide. In one embodiment, the ceramic plates are Al₂O₃. The Al₂O₃ ceramic plates may be undoped or may be doped. For example, the Al₂O₃ may be doped with Titanium dioxide (TiO₂) or a transition metal oxide.

The mounting plate 162 is coupled to the bottom 110 of the chamber body 102 and includes passages for routing utilities (e.g., fluids, power lines, sensor leads, etc.) to the cooling plate 164 and the other components of the ceramic stack 166. The cooling plate 164 and/or ceramic stack 166 may include one or more optional embedded heating elements 176, optional embedded thermal isolators 174 and/or optional conduits 168, 170 to control a lateral temperature profile of the substrate support assembly 148. In one embodiment, a thermal gasket 138 is disposed on at least a portion of the cooling plate 164.

The conduits 168, 170 may be fluidly coupled to a fluid source 172 that circulates a temperature regulating fluid through the conduits 168, 170. The embedded thermal isolators 174 may be disposed between the conduits 168, 170 in one embodiment. The embedded heating elements 176 are regulated by a heater power source 178. The conduits 168, 170 and embedded heating elements 176 may be utilized to control the temperature of the ceramic stack 166, thereby heating and/or cooling the ceramic stack 166 and a substrate (e.g., a wafer) being processed. In one embodiment, the ceramic stack 166 includes two separate heating zones that can maintain distinct temperatures. In another embodiment, the ceramic stack 166 includes four different heating zones that can maintain distinct temperatures.

Alternatively, the ceramic stack 166 may include greater or fewer heating zones. The temperature of the electrostatic ceramic stack 166 and the thermally conductive base may be monitored using multiple temperature sensors 190, 192, which may be monitored using a controller 199.

The ceramic stack 166 may further include multiple gas passages such as grooves, mesas and other surface features that may be formed in an upper surface of the ceramic stack 166. The gas passages may be fluidly coupled to a source of a heat transfer (or backside) gas, such as He via holes drilled in the ceramic stack 166. In operation, the backside gas may be provided at controlled pressure into the gas passages to enhance the heat transfer between the ceramic stack 166 and the substrate 144. Features such as the gas passages, grooves, mesas, sealing band, etc. may be formed using laser material processing in embodiments.

In one embodiment, the ceramic stack 166 includes at least one clamping electrode 180 controlled by a chucking power source 182. The clamping electrode 180 (also referred to as a chucking electrode) may further be coupled to one or more RF power sources 184, 186 through a matching circuit 188 for maintaining a plasma formed from process and/or other gases within the processing chamber 100. The one or more RF power sources 184, 186 are generally capable of producing an RF signal having a frequency from about 50 kHz to about 3 GHz and a power of up to about 10,000 Watts. In one embodiment, an RF signal is applied to the metal base, an alternating current (AC) is applied to the heater and a direct current (DC) is applied to the clamping electrode 180.

FIG. 2A illustrates a ceramic base 230A including a resistive heating trace embedded in the ceramic base, according to some embodiments.

In some embodiments, a system 200A can include ceramic base 230A. Ceramic base 230A can be a heating ceramic of a ceramic stack of a substrate support such as an ESC. Ceramic base 230A can include a resistive heating trace 240A embedded in the ceramic base 230A. Resistive heating trace 240A can include a set of elongated parallel trace segments 241A, 242A, and 243A. Each of elongated parallel trace segments 241A, 242A, and 243A can extend across a major surface of the ceramic base 230A. Resistive heating trace 240A can cover at least a portion of the surface area of ceramic base 230A to heat the base uniformly. In some embodiments, ceramic base 230A includes more than one resistive heating trace that covers the entire surface area of the ceramic base 230A to heat the base.

In some embodiments, resistive heating trace 240A can be screen printed onto the ceramic base 230A. In some embodiments, resistive heating trace 240A can be applied to ceramic base 230A by thick film printing, thin film deposition, photolithography and etching, laser ablation, direct write technologies such as inkjet or aerosol jet printing, etc.

Resistive heating trace 240A can include a first terminal 211A coupled to a first elongated parallel trace segment 241A of the set of elongated parallel trace segments. The first terminal 211A can be disposed a first radial distance 251A from a center of the ceramic base 230A. A second terminal 212A of resistive heating trace 240A can be coupled to a second elongated parallel trace segment 242A of the set of elongated parallel trace segments. The second terminal 212A can be disposed a second radial distance 252A from the center of the ceramic base 230A, the second radial distance being either greater than or less than, but not equal to, the first radial distance. In some embodiments, by disposing first terminal 211A at the first radial distance 251A from the center of ceramic base 230A and second terminal 212A at the second radial distance 252A from the center of ceramic base 230A, first terminal 211A and second terminal 212A are not adjacent to each other, eliminating potential cold spots between first terminal 211A and second terminal 212A.

In some embodiments, resistive heating trace 240A includes a set of bridging segments 221A and 222A that adjoin adjacent elongated parallel trace segments of the set of elongated parallel trace segments 241A, 242A, and 243A. For example, bridging segment 221A adjoins elongated parallel trace segments 241A and 243A. Bridging segment 222A adjoins elongated parallel trace segments 243A and 242A.

In some embodiments, the first terminal 211A is disposed on a first horizontal plane and the second terminal is disposed on a second horizontal plane 212A. The first terminal 211A, which is disposed on the first plane, is coupled to the second terminal 212A, which is disposed on the second plane, through a via (e.g., a vertical via). In some embodiments, one of the terminals (e.g., the first terminal 211A on the first plane) may be coupled to the via, which is coupled to a bus bar 280A, with the bus bar 280A being coupled to the other terminal (e.g., the second terminal 212A on the second plane). The via can be made of a conductive metal material or any other suitable material for coupling the terminals and elongated parallel trace segments. In some embodiments, the first elongated parallel trace segment 241a, which is coupled to the first terminal 211A on the first plane, may be coupled to the second elongated parallel trace segment 242A, which is coupled to the second terminal 212A on the second plane, in series or parallel through the via.

In some embodiments, a ceramic base may include two or more sets of terminals corresponding to additional sets of elongated parallel trace segments. Each set of terminals corresponding to a set of elongated parallel trace segments can be coupled to the set of elongated parallel trace segments in series or parallel through a via. For example, a ceramic base having three sets of terminals corresponding to three additional sets of elongated parallel trace segments may include a first set of terminals corresponding to a set of elongated parallel trace segments that are coupled to the set of elongated parallel trace segments in series through a via, a second set of terminals corresponding to a set of elongated parallel trace segments that are coupled to the set of elongated parallel trace segments in parallel through a via, and a third set of terminals corresponding to a set of elongated parallel trace segments that are coupled to the set of elongated parallel trace segments in series through a via. For any number of sets of terminals corresponding to a set of elongated parallel trace segments, each set of elongated parallel trace segments can be coupled to the terminals in series or parallel through a via.

In some embodiments, a third horizontal plane, a fourth horizontal plane, a fifth horizontal plane, a sixth horizontal plane, and so on, may be disposed between the first horizontal plane and the second horizontal plane. A third elongated parallel trace segment, a fourth elongated parallel trace segment, a fifth elongated parallel trace segment, a sixth elongated parallel trace segment, and so on, may be disposed on each of the third horizontal plane, the fourth horizontal plane, the fifth horizontal plane, the sixth horizontal plane, and so on. In some embodiments, each of the additional horizontal planes disposed between the first horizontal plane and the second horizontal plane may include portions of the first elongated parallel trace segment and/or second elongated parallel trace segment. Any number of horizontal planes (e.g., 10-15 horizontal planes) may be included and any number of elongated parallel trace segments may extend across major surfaces of the horizontal planes. Any number of bridging segments may be included to adjoin adjacent elongated parallel trace segments.

In some embodiments, an interplane thickness can range between 5 μm and 500 μm. However, other suitable interplane thicknesses may also be used, such as thicknesses below 5 μm or above 500 μm. Similarly, an elongated parallel trace segment thickness can range between 5 μm and 400 μm, but other suitable elongated parallel trace segment thicknesses may also be used, such as thicknesses below 5 μm or above 400 μm. Bus thicknesses can also range between 5 μm and 400 μm, with other suitable bus thicknesses being possible as well, such as thicknesses below 5 μm or above 400 μm.

FIG. 2B illustrates a ceramic base 230B including a resistive heating trace embedded in the ceramic base, according to some embodiments.

In some embodiments, a system 200B includes ceramic base 230B. Ceramic base 230B can be a heating ceramic of a ceramic stack of a substrate support such as an ESC. Ceramic base 230B can include a resistive heating trace 240B embedded in the ceramic base 230B. Resistive heating trace 240B can include a set of elongated parallel trace segments 241B, 242B, and 243B. Each of elongated parallel trace segments 241B, 242B, and 243B can extend across a major surface of the ceramic base 230B. Resistive heating trace 240B can cover at least a portion of the surface area of ceramic base 230B to heat the base uniformly. In some embodiments, ceramic base 230B includes more than one resistive heating trace that covers the entire surface area of the ceramic base 230B to heat the base.

Resistive heating trace 240B can include a first terminal 211B coupled to a first elongated parallel trace segment 241B of the set of elongated parallel trace segments. The first terminal 211B can be disposed a first radial distance 251B from a center 260B of the ceramic base 230B. A second terminal 212B of resistive heating trace 240B can be coupled to a second elongated parallel trace segment 242B of the set of elongated parallel trace segments. The second terminal 212B can be disposed a second radial distance 252B from the center 260B of the ceramic base 230B. In some embodiments, by disposing first terminal 211B at the first radial distance 251B from the center of ceramic base 230B and second terminal 212B at the second radial distance 252B from the center 260B of ceramic base 230B, first terminal 211B and second terminal 212B are not adjacent to each other, eliminating potential cold spots between first terminal 211B and second terminal 212B.

In some embodiments, resistive heating trace 240B includes a set of bridging segments 221B and 222B that adjoin adjacent elongated parallel trace segments of the set of elongated parallel trace segments 241B, 242B, and 243B. In some embodiments, at least one elongated trace segment of the set of elongated trace segments or at least one bridging segment of the plurality of bridging segments is disposed between the first terminal 211B and the second terminal 212B. For example, both of bridging segments 221B and 222B are disposed between first terminal 211B and second terminal 212B, eliminating any potential cold spot between the two terminals. Bridging segment 221B can adjoin elongated parallel trace segments 241B and 243B. Bridging segment 222B can adjoin elongated parallel trace segments 243B and 242B.

In some embodiments, resistive heating trace 240B can be screen printed onto the ceramic base 230B. In some embodiments, resistive heating trace 240B can be applied to ceramic base 230B by thick film printing, thin film deposition, photolithography and etching, laser ablation, direct write technologies such as inkjet or aerosol jet printing, etc.

In some embodiments, resistive heating traces 240A-B can be embedded within a ceramic base (e.g., ceramic base 230A or 230B) of a ceramic stack of a substrate support system. Resistive heating traces 240A-B can include two terminals placed at different radial distances from a center of the ceramic base, helping to eliminate cold spots between the two terminals. In some embodiments, bridging segments can be strategically positioned for enhanced thermal distribution uniformity. For example, bridging segments 221B and 222B can connect adjacent elongated parallel trace segments 241B, 242B, and 243B, and can be disposed between terminals 211B and 212B, further helping to eliminate cold spots and enhancing temperature distribution uniformity.

In some embodiments, the first terminal 211B can be disposed on a first horizontal plane and the second terminal 212B is disposed on a second horizontal plane. The first terminal 211B (disposed on the first plane) can be coupled to the second terminal 212B (disposed on the second plane) through a via (e.g., a vertical via). In some embodiments, one of the terminals (e.g., the first terminal 211B on the first plane) can be coupled to the via which is coupled to a bus bar 280B, the bus bar 280B being coupled to the other terminal (e.g., the second terminal 212B on the second plane). The via can be, for example, a conductive metal material or any other suitable material for coupling the terminals and elongated parallel trace segments. In some embodiments, the first elongated parallel trace segment 241B (coupled to the first terminal 211B on the first plane) can be coupled to the second elongated parallel trace segment 242B (coupled to the second terminal 212B on the second plane) in series or parallel through the via.

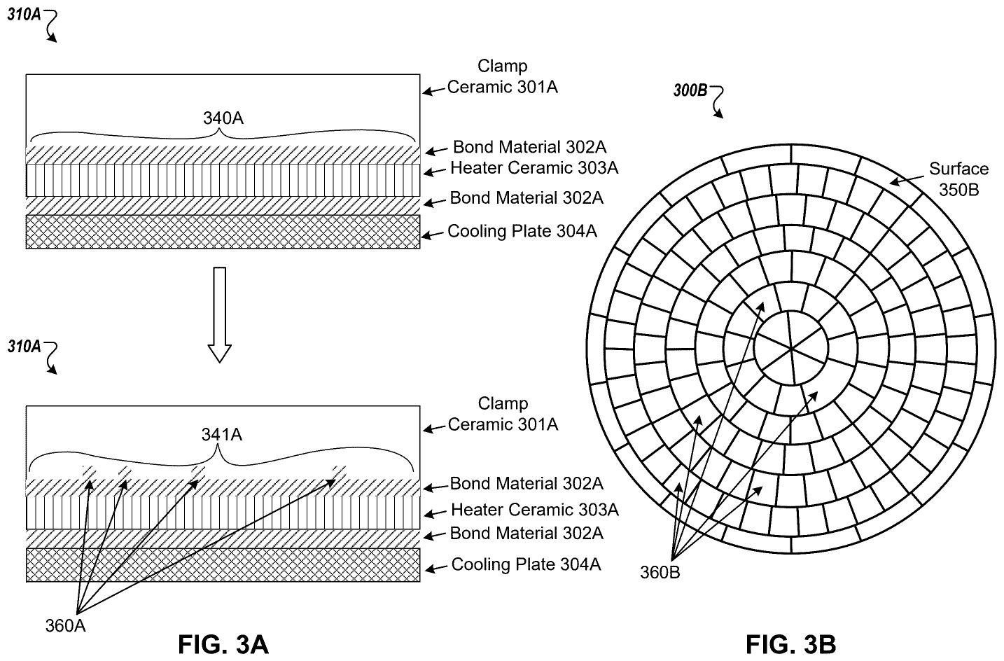

FIG. 3A illustrates modifying a surface profile of a component of a ceramic stack 310A based on an updated surface profile, according to some embodiments.

In some embodiments, a system can include a ceramic base (e.g., heater ceramic 303A) and a resistive heating element embedded in the ceramic base. The resistive heating element can include a set of elongated parallel trace segments, each trace segment extending across a major surface of the ceramic base. The resistive heating element can include a first terminal coupled to a first elongated parallel trace segment of the set of elongated parallel trace segments and disposed a first radial distance from a center of the ceramic base. The resistive heating element can include a second terminal coupled to a second elongated parallel trace segment of the set of elongated parallel trace segments and disposed a second radial distance from the center of the ceramic base.

The resistive heating element can be printed (e.g., using screen printing, ink jet printing, lamination, lithography, etc.) on the ceramic base.

The system can include ceramic stack 310A, the ceramic base being configured as a component of the ceramic stack. In some embodiments, the ceramic base can be referred to as the heater ceramic 303A. The heater ceramic can include the embedded resistive heating trace. The system can further include a processing device coupled to a memory. The processing device can perform physics-based optimization of a surface of a component of the ceramic stack 310A (e.g., using a physics-based optimization model).

In some embodiments, the processing device provides inputs to a physics-based model. Inputs can include current surface profile data (e.g., including dimensions of the ceramic stack). The inputs can further include material composition data (e.g., thermal conductivity and heat capacity). The inputs can further include target thermal uniformity data that specifies the target temperature distribution. The inputs can further include current thermal uniformity data of the component.

For example, the processing device can determine thermal uniformity data of the ceramic stack or a component of the ceramic stack. In some embodiments, the thermal uniformity data of the ceramic stack includes thermal uniformity data of a component of the ceramic stack or thermal uniformity data of the entire substrate support system. For example, the processing device can determine thermal uniformity data of at least one of the clamp ceramic 301A, heater ceramic 303A, cooling plate 304A, bond material 302A, etc. In some embodiments, thermal uniformity data of the surface of a component of the ceramic stack 310A, can be determined using heat sensors during the execution of a process recipe or step that involves heating. For example, temperature sensors such as thermocouples or infrared sensors can be placed at various points across the surface of the ceramic stack. As the process recipe proceeds, these sensors continuously monitor and record the temperature at their respective locations. The thermal data can be analyzed in real-time or post-process to assess the thermal uniformity across the surface. This analysis can identify any significant temperature gradients or anomalies that indicate non-uniform heating, enabling adjustments (e.g., surface profile adjustments) to optimize thermal distribution and improve process outcomes.

In some embodiments, the processing device can determine the thermal uniformity data of the ceramic stack 310A using the physics-based optimization model (e.g., without running a process and taking temperature measurements). The physics-based optimization model integrates fundamental principles such as heat transfer, thermodynamics, and material science to simulate the thermal behavior of the ceramic stack 310A. Using the input parameters such as a current surface profile, material properties, environmental conditions, and process settings, the model can calculate the expected temperature distribution across the ceramic stack.

In some embodiments, the physics-based optimization model can operate on first principles of physics, incorporating fundamental laws of thermodynamics and heat transfer. The physics-based model can simulate the thermal behavior of the ceramic 310A stack, accounting for various factors such as heat generation from embedded heating elements, thermal conductivity of materials, heat loss through cooling channels, and the influence of surrounding environmental conditions. Using specific parameters related to the design and material properties of the electrostatic chuck, the model can accurately predict temperature distributions and identify potential thermal non-uniformities.

In some embodiments, the processing device can determine a target thermal uniformity profile of ceramic stack 310A. This profile can represent a target temperature distribution across the ceramic stack 310A that achieves target thermal performance.

In some embodiments, the processing device can determine a surface profile (e.g., a current surface profile) of a component of the ceramic stack 310A. The component of the ceramic stack can be, for example, clamp ceramic 301A, bond material 302A, heater ceramic 303A, cooling plate 304A, etc. The surface profile can be a bottom surface profile or a top surface profile. For example, a bottom surface profile 340A of clamp ceramic 301A can be determined using metrology techniques such as laser scanning, white light interferometry, or atomic force microscopy (AFM), etc. to capture surface topography data (e.g., surface profile data). Metrology devices can generate measurements of surface features, including variations in height, roughness, and flatness. The collected data can then be processed and analyzed by the processing device to determine a surface profile. In some embodiments, surface profile 340A can be substantially flat.

In some embodiments, the processing device can determine an updated surface profile of the component of the ceramic stack 310A based on a physics-based optimization (e.g., using the physics-based optimization model). For example, the processing device can be provided the current profile data of the component of the ceramic stack 310A, current thermal uniformity data, and a target thermal uniformity data as input to physics-based optimization model. The processing device can receive outputs of the physics-based optimization model including an updated surface profile derived based on the inputs (e.g., current surface profile data, current thermal uniformity data, and target thermal uniformity data).

For example, the updated surface profile may be for an upper surface of the component of the ceramic stack 310A, and may include changes in thickness, size and/or shape of features on the surface of the component. In some embodiments, the surface profile of the component is substantially flat and the updated surface profile includes changes to the profile such as removing or adding material from the surface profile of the component. The surface profile may be for a bottom surface or a top surface of a component of the ceramic stack. For example, an updated surface profile 341A of the bottom surface of clamp ceramic 301A can be determined.

In some embodiments, to determine an updated surface profile of the component of the ceramic stack 310A based on a physics-based optimization, the processing device determines an optimal bond layout for a bond layer of the ceramic stack 310A. For example, an optimal bond layout for bond material 302A can be determined. In some embodiments, the bond layer is modeled with varying thermal conductivity. For example, the thermal conductivity of the bond layer (e.g., bond material 302A) is not assumed to be uniform throughout its entire volume. Instead, it can be represented as having different thermal conductivities at different locations within the layer. This variation can be due to factors such as material composition differences, thickness variations, or temperature-dependent changes in thermal properties. By varying the thermal conductivity of a layer of the ceramic stack 310A (e.g., the bond material 302A), the physics-based optimization model can determine a varied thermal conductivity profile across the layer that optimizes the thermal uniformity. The updated surface profile of the bond layer can then be determined based on the model of the bond layer having varied thermal conductivity. In some embodiments, holes can be drilled and filled with materials of varying thermal conductivity to achieve a target thermal uniformity profile based on thermal uniformity data.

For example, ceramic clamp 301A may have a different thermal conductivity than bond material 302A. By modeling ceramic clamp 301A with varied thermal conductivity, the processing logic can determine an updated surface profile of ceramic clamp 301A. Subsequently, the ceramic clamp 301A can be modified to the new surface profile and be filled in with bond material 302A as seen in features 360A. By varying the thermal conductivity of the profile, the thermal uniformity can be tuned.

The processing device can then cause the surface profile of the component of the ceramic stack to be modified based on the updated surface profile.

In some embodiments, laser material processing can be performed to remove material from the surface of the component of the ceramic stack. For example, bottom surface profile 341A of ceramic clamp 301A can be modified using laser material processing based on the updated surface profile. Such shaping of bottom surface profile 341A via laser material processing can form features 360A to regulate and correct the thermal profile of the ceramic stack 310A. In some embodiments, bond material 302A can be a flowable material that fills the area formed by material removal via the laser material processing.

By using laser material processing, the thermal uniformity of the ceramic stack 310A can be increased due to the ability to remove precise amounts of material using laser material processing. Laser material processing can involve the use of focused laser beams to modify, cut, weld, or otherwise alter the properties of various materials. The process can work through the interaction between the intense light of the laser and the material being processed. In laser material processing, laser light can be generated by exciting atoms or molecules within a laser medium, such as a gas, solid-state crystal, or semiconductor. The laser beam can be focused using lenses or mirrors to concentrate its energy into a small spot to achieve high power density and precision in the material processing. When the focused laser beam interacts with the material, several processes can occur depending on the properties of both the laser and the material. Examples of processes include absorption, melting, vaporization, annealing, hardening, and chemical reactions. Laser tuning parameters for modifying the surface of a component of ceramic stack 310A can include average power, pulse energy, pulse duration, dwell time, beam scanning speed, repetition rate, hatch distance, hatch type, rastering type, milling strategy (e.g., to tune the surface roughness), and/or the like. Monitoring systems may be employed to ensure consistent quality and accuracy in the processed parts. Laser material processing may be performed by moving a laser source and/or a ceramic plate being processed (e.g., by a support bed that may be movable in x, y and/or z). In some embodiments, the laser beam may have a fixed direction (e.g., may be vertical). In some embodiments, the direction of the laser beam may vary, such as by rotating a laser source.

FIG. 3B illustrates modifying a surface profile of a component 300B of a ceramic stack 310A based on an updated surface profile, according to some embodiments.

In some embodiments, to determine the thermal uniformity of the ceramic stack 310A, the processing can partition a surface 350B (e.g., top surface or bottom surface) of a component 300B of the ceramic stack (e.g., clamp ceramic 301A, bond material 302A, heater ceramic 303A, cooling plate 304A, etc.) into a set of discrete segments 360B to create a segmented representation of the surface 350B of the component 300B of the ceramic stack 310A for a physics-based optimization model. The processing device can generate a mesh for the segmented surface 350B representing metrology and/or thermal properties of each discrete segment of the set of discrete segments.

In some embodiments, to determine the updated surface profile of the component 300B of the ceramic stack 310A, the processing device can determine a thickness profile of the component 300B of the ceramic stack 310A based on a determined thickness at each segment of the segmented representation of the surface 350B of the component 300B of the ceramic stack 310A.

In some embodiments, the bond layer is modeled with varying thermal conductivity. For example, the thermal conductivity of the bond layer (e.g., bond material 302A) is not assumed to be uniform throughout its entire volume. Instead, it can be represented as having different thermal conductivities at different locations (e.g., at each discrete segment of the set of discrete segments 360B) within the layer. This variation can be due to factors such as material composition differences, thickness variations, or temperature-dependent changes in thermal properties. The updated surface profile of the bond layer can then be determined based on the model of the bond layer having varied thermal conductivity.

In some embodiments, the updated surface profile of the component 300B of the ceramic stack 310A can include an optimal gray scale bond material profile. For example, the updated surface profile can be a freeform polynomial shape or a linear approximation of a freeform polynomial shape. Alternatively, the updated surface profile of the component 300B of the ceramic stack 310A can include an optimal binary bond material layout. For example, a parameter sweep of the surface can be run with the physics-based optimization model with no bond in each segment helping to determine a binary layout to meet a target thermal profile. In some embodiments, each discrete segment of the set of discrete segments 360B can be treated as a filled or non-filled portion of the bond material layout. Assuming there are N number of discrete segments, then N simulations are needed. In some embodiments, simulations can be sped by varying multiple segments that are thermal isolated from each other.

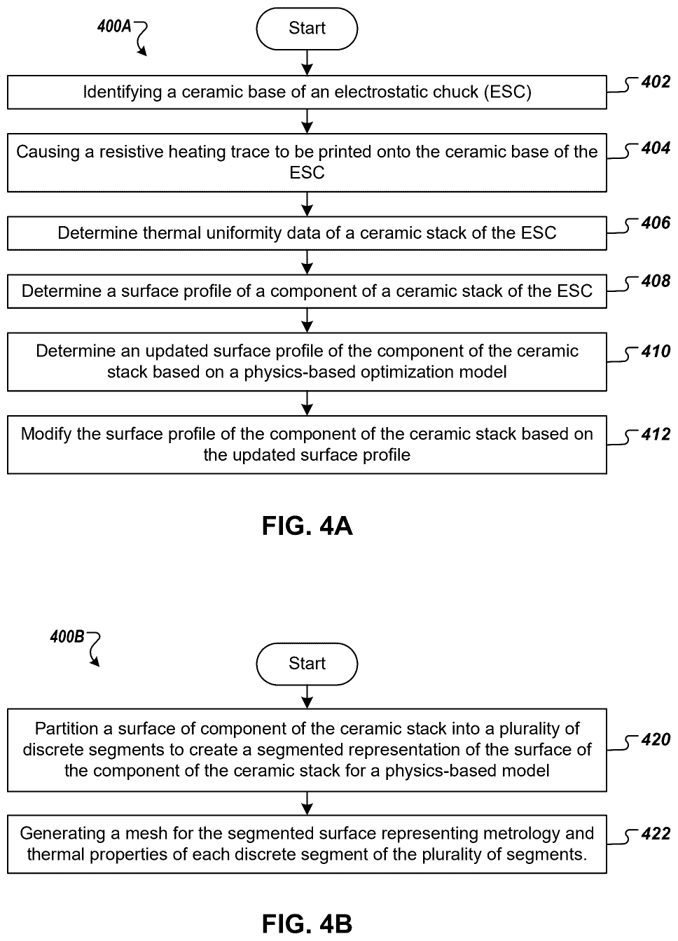

FIGS. 4A-B are flow diagrams of methods associated with thermal management in substrate supports, according to some embodiments. One or more operations of methods 400A-B may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiments, a non-transitory storage medium stores instructions that when executed by a processing device (e.g., of processing system, of) cause the processing device to perform one or more operations of one or more of methods 400A-B.

For simplicity of explanation, methods 400A-B is depicted and described as a series of operations. However, operations in accordance with this disclosure can occur in various orders and/or concurrently and with other operations not presented and described herein. Furthermore, not all illustrated operations may be performed to implement methods 400A-B in accordance with the disclosed subject matter. In addition, those skilled in the art will understand and appreciate that methods 400A-B could alternatively be represented as a series of interrelated states via a state diagram or events.

Referring to FIG. 4A, in some embodiments, at block 402 the processing logic implementing method 400A may identify a ceramic base of an electrostatic chuck (ESC).

At block 404, the processing logic causes a resistive heating trace to be printed onto the ceramic base of the ESC.

In some embodiments, the resistive heating trace includes a set of elongated parallel trace segments that each extend across a major surface of the ceramic base. The resistive heating trace can further include a first terminal coupled to a first elongated parallel trace segment of the set of elongated parallel trace segments and disposed a first radial distance from a center of the ceramic base. The resistive heating trace can further include a second terminal coupled to a second elongated parallel trace segment of the set of elongated parallel trace segments and disposed a second radial distance from the center of the ceramic base. In some embodiments, the resistive heating trace further includes a set of bridging segments that adjoin adjacent elongated parallel trace segments of the set of elongated parallel trace segments. In some embodiments, at least one elongated trace segment of the set of elongated trace segments or at least one bridging segment of the set of bridging segments is disposed between the first terminal and the second terminal.

At block 406, the processing logic determines thermal uniformity data of a ceramic stack of the ESC. In some embodiments, the thermal uniformity data of the ceramic stack of the ESC can be determined using sensors in a manufacturing system. For example, sensors can determine thermal data of the ceramic stack of the ESC during a processing recipe or processing step. In some embodiments, the determining of the thermal uniformity data of the ceramic stack of the ESC is based on a physics-based optimization model.

At block 408, the processing logic determines a surface profile of a component of a ceramic stack of the ESC. The surface profile of the component of the ceramic stack of the ESC can include dimensions of the surface of the component (e.g., thickness, width, etc.). The surface profile of the component of the ceramic stack can be determined using metrology devices (e.g., of a manufacturing system).

At block 410, the processing logic determines an updated surface profile of the component of the ceramic stack based on a physics-based optimization model. For example, the processing logic can provide input including surface profile data of the ceramic stack, the thermal uniformity data of the ceramic stack, and target thermal uniformity data of the ceramic stack to the physics-based optimization model and receive as output updated surface profile of a component of the ceramic stack.

In some embodiments, the determining of an updated surface profile of the component of the ceramic stack based on a physics-based optimization includes determining an optimal bond layout. In some embodiments, the bond is modeled with varying thermal conductivity. For example, by modeling thermal conductivity as a variable parameter, allowing for adjustments in the bond's material properties or distribution of an optimal bond layout that improves thermal uniformity across the ceramic stack can be determined.

In some embodiments, to determine an update surface profile for the component of the ceramic stack using a physics-based optimization model, profile data is provided as an input. For example, profile data can include the initial surface profile of the component and the other geometric dimensions of the component. An initial surface profile and geometric dimension provides a starting point for the optimization algorithm. Further, profile data can include specific locations of heating zones and terminals, material properties, specific heat capacity, electrical resistivity, etc.

In some embodiments, to determine an update surface profile for the component of the ceramic stack using a physics-based optimization model, performance data is provided as an input. Performance data can include thermal uniformity data. In some embodiments, the physics-based optimization model iteratively adjusts the surface profile to minimize temperature variation and achieve the desired thermal performance (e.g., a target thermal uniformity) adhering to constraints on physical thickness and manufacturing limitations. In some embodiments, a target thermal uniformity can be provided as input to the physics-based optimization model.

At block 412, the processing logic causes the surface profile of the component of the ceramic stack to be modified based on the updated surface profile. In some embodiments, the modifying of the surface profile of the component of the ceramic stack surface based on the updated surface profile includes performing laser material processing of the surface profile of the component of the ceramic stack surface.

By using laser material processing, the thermal uniformity of the ceramic stack can be increased due to the ability to remove precise amounts of material using laser material processing. Laser material processing can involve the use of focused laser beams to modify, cut, weld, or otherwise alter the properties of various materials. Laser material processing may be performed by moving a laser source and/or a ceramic plate being processed (e.g., by a support bed that may be movable in x, y and/or z).

Referring to FIG. 4B, in some embodiments, at block 420 the processing logic implementing method 400B may partition a surface of a component of the ceramic stack into a set of discrete segments to create a segmented representation of the surface of the component of the ceramic stack for a physics-based model.

At block 422, the processing logic generates a mesh for the segmented surface representing metrology and thermal properties of each discrete segment of the set of segments.

In some embodiments, the determining of an updated surface profile of the component of the ceramic stack based on a physics-based optimization of method 400A includes determining a thickness profile of the component of the ceramic stack based on a determined thickness at each segment of the segmented representation of the component of the ceramic stack.

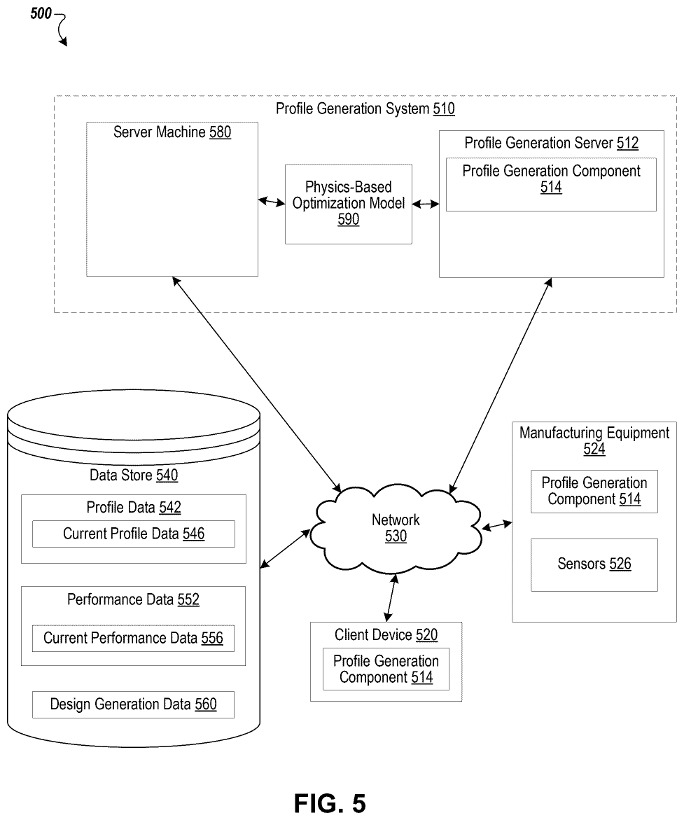

FIG. 5 is a block diagram illustrating an example system architecture 500, according to certain embodiments.

The system 500 can include a client device 520, manufacturing equipment 524, sensors 526, a profile generation system 510, and a data store 540. In some embodiments, the profile generation system 510 includes a profile generation server 512. In some embodiments, the profile generation system 510 further includes server machine 580.

In some embodiments, one or more of the client device 520, manufacturing equipment 524, sensors 526, profile generation server 512, data store 540, and/or server machine 580 are coupled to each other via a network 530 for generating predictive data 560 to generate profiles (e.g., feature patterns) and perform laser material processing to create features on a ceramic plate of a substrate support system. In some embodiments, network 530 is a public network that provides client device 520 with access to the profile generation server 512, data store 540, and other publicly available computing devices. In some embodiments, network 530 is a private network that provides client device 520 access to manufacturing equipment 524, sensors 526, data store 540, and other privately available computing devices. In some embodiments, network 530 includes one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

Manufacturing equipment 524 can produce products, such as heater ceramics following a recipe or a process. In some embodiments, manufacturing equipment can include sensors (e.g., sensors 526) configured to generate sensor measurement values (e.g., sensor data) during a process performed at manufacturing equipment 524. For example, sensor 526 can gather thermal uniformity data of a substrate support system, a ceramic stack of a substrate support system, or a component of a ceramic stack during a processing operation. The sensors can be operatively coupled to the system controller. In some embodiments, the sensors can be configured to generate a sensor measurement values during particular instances of a processing operation.

The system controller can, for example, generate a thermal uniformity profile based on sensor values from the from the sensors 526. In some embodiments, thermal uniformity data can represent the temperature distribution across a substrate support system, a ceramic stack of a substrate support system, or a component of a ceramic stack during semiconductor manufacturing processes. Thermal uniformity data can be visualized as a heat map, showing varying temperatures across different regions. Thermal uniformity data can be visualized as a collection of discrete temperature readings. In some embodiments, thermal uniformity data can be gathered by embedded temperature sensors (e.g., sensors 526) throughout a processing operation. Thermal uniformity data can be used to monitoring the uniform application of heat or cooling, helping to ensure process consistency, material integrity, and the quality of the fabricated semiconductor devices. Sensors 526 may additionally or alternatively include a metrology device, such as a reflectometry device that measures a surface (e.g., film thickness) of a substrate processed using a substrate support. A thickness profile or other surface profile of the substrate may be determined from the metrology data, which may correlate to a temperature uniformity profile.

By improving thermal uniformity data (e.g., using profile generation based on performance data), the process consistency, material integrity, and the quality of the fabricated devices can be improved (e.g., by reducing hot and cold spots). By analyzing thermal uniformity data, hotspots can be identified and a target profile for a bottom surface and/or top surface of a component of a ceramic stack of a substrate support system can be determined. Laser material processing can be performed to remove material from the bottom surface and/or top surface of component of a ceramic stack of a substrate support system to help ensure a uniform thermal profile, improve process parameters, and enhance the overall efficiency and outcome of the manufacturing process.

In some embodiments, the data store 540 is memory (e.g., random access memory), a drive (e.g., a hard drive, a flash drive), a database system, or another type of component or device capable of storing data. In some embodiments, data store 540 includes multiple storage components (e.g., multiple drives or multiple databases) that span multiple computing devices (e.g., multiple server computers).

In some embodiments, the manufacturing equipment 524 (e.g., deposition chamber, etch chamber, and/or the like) is part of a substrate processing system (e.g., integrated processing system). The manufacturing equipment 524 includes one or more of a controller, an enclosure system (e.g., substrate carrier, front opening unified pod (FOUP), a factory interface (e.g., equipment front end module (EFEM)), a load lock, a transfer chamber, one or more processing chambers, a robot arm (e.g., disposed in the transfer chamber, disposed in the front interface, etc.), and/or the like. In some embodiments, the manufacturing equipment 524 includes components of substrate processing systems.

In some embodiments, the client device 520 includes a computing device such as Personal Computers (PCs), laptops, mobile phones, smart phones, tablet computers, netbook computers, etc. In some embodiments, the client device 520 includes a profile generation component 514. In some embodiments, the profile generation component 514 is included in the profile generation system 510 (e.g., instead of being included in client device 520). Client device 520 includes an operating system that can allow users to consolidate, generate, view, or edit data, provide directives to the profile generation system 510 (e.g., machine learning processing system), etc.

In some embodiments, performance data 542 includes thermal uniformity data of a substrate support system and/or ceramic stack. In some embodiments, performance data can include current performance data 556 (e.g., current thermal uniformity) and target performance data 557 (e.g., a target thermal uniformity).

In some embodiments, profile data 542 includes dimensional data of a substrate support system and/or ceramic stack. In some embodiments, profile data 542 includes dimensional data of a surface profile of a substrate support system and/or ceramic stack. Profile data 542 can further include other material properties of a substrate support system and/or ceramic stack (e.g., thermal conductivity, specific heat capacity, thermal expansion coefficient, thermal diffusivity, electrical resistivity, dielectric constant, etc.). Profile data 542 can include current profile data 546 (e.g., current surface profile) and updated profile data 547 (e.g., updated surface profile).

In some embodiments, profile generation component 514 receives one or more of user input (e.g., via a graphical user Interface (GUI) displayed on the client device 520), performance data 552 (e.g., thermal uniformity data, target thermal uniformity data), profile data 542 (e.g., current surface profile data), etc. In some embodiments, profile generation component 514 transmits data (e.g., user input, performance data 552, profile data 542, to the profile generation system 510, receives profile generation data 560 from the profile generation system 510, and outputs at least one of an updated surface profile (e.g., updated profile data 547 based on profile generation data 560). In some embodiments, the profile generation component 514, stores data (e.g., user input, profile data 542, performance data 552, etc.) in the data store 540 and the profile generation server 512 retrieves the data from the data store 540. In some embodiments, the profile generation server 512 stores output data (e.g., profile generation data 560) of the physics-based optimization model 590 in the data store 540 and the client device 520 retrieves the output from the data store 540.

In some embodiments, current profile data 546 can be, for example, data representing the current profile of a surface of a component of a ceramic stack of an ESC. In some embodiments, current profile data 546 can be, for example, property data of component of a ceramic stack of an ESC (e.g., including dimensions of a surface profile, etc.). In some embodiments, performance data 556 can be, for example, data representing a thermal uniformity profile of the component of the ceramic stack and/or a substrate (e.g., wafer) supported by the substrate support system (e.g., ESC) before modification.

In some embodiments, the profile generation server 512, and server machine 580 each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc.

The profile generation server 512 can include a profile generation component 514. In some embodiments, the profile generation component 514 identifies (e.g., receives from the client device 520, retrieves from the data store 540) performance data 552 (e.g., temperature uniformity data) and profile data 542, and generates profile generation data 560 associated with updated profile 547, updated profile generation (e.g., an updated profile), target profile generation, etc. In some embodiments, the profile generation component 514 uses one or more physics-based optimization models 590 to determine the profile generation data 560. In some embodiments, physics-based optimization model 590 can operate on first principles of physics, incorporating fundamental laws of thermodynamics and heat transfer. The physics-based optimization model can simulate the thermal behavior of the ceramic stack, individual components of the ceramic stack, or the entire substrate support system, accounting for various factors such as heat generation from embedded heating elements, thermal conductivity of materials, heat loss through cooling channels, and the influence of surrounding environmental conditions. By inputting specific parameters related to the design and material properties of ESC, the model can accurately predict temperature distributions and identify potential thermal non-uniformities.

In some embodiments, profile generation includes determining updated surface profiles, refinement of existing surface profiles, determining laser material processing parameters for laser material processing, determining a target surface profile for a top surface or a bottom surface of a component of the ceramic stack (e.g., heater ceramic, bond ceramic, etc.) or an additional component of the substrate support system, etc.

In some embodiments, profile generation, for example, based on performance data 552 and profile data 542, may be done using a physics-based optimization model (e.g., physics-based optimization model 590). In some embodiments, the profile generation system 510 (e.g., profile generation server 512, profile generation component 514) generates profile generation data 560 using the physics-based optimization model.

In some embodiments, the sensors 526 collect performance data 552 (e.g., thermal uniformity data, such as historical temperature sensor values and current temperature sensor values) of the ceramic stack and/or the substrate support system. In some embodiments, the performance data 552 (e.g., current performance data 556, etc.) is processed, e.g., by the client device 520 and/or by the profile generation server 512. In some embodiments, processing of the performance data 552 includes generating updated surface profiles and/or target profiles. In some embodiments, the updated surface profiles can be a refinement to an existing surface profile (e.g., profile data) of a component of a ceramic stack of a substrate support system or another component of the substrate support system.

In some embodiments, the data store 540 stores one or more of performance data 552, profile data 542, and/or profile generation data 560. In some embodiments, data store 540 can be configured to store data that is not accessible to a user of the manufacturing system. For example, performance data, profile data, process data, contextual data, etc. obtained for a component of a ceramic stack of a substrate support system of the manufacturing system is not accessible to a user (e.g., an operator) of the manufacturing system.

Performance data 552 may include current performance data 556. In some embodiments, profile data 542 may include for example, a target profile for a surface of a component of a ceramic stack.

Current data may include one or more of current profile data 546 and/or current performance data 556 (e.g., at least a portion to be input into the physics-based optimization model 590).

By providing performance data 552 and profile data 542 to model 590 and receiving profile generation data 560 from the model 590, and using such output of the model 590 to update a surface profile of a component a ceramic stack of a substrate support, system 500 has the technical advantage of enhancing thermal uniformity, enabling even heat distribution and improving process uniformity and device quality.

In some embodiments, profile generation system 510 further includes and server machine 580.

Profile generation component 514 provides current performance data 556 and current design data 546 (e.g., as input) to the physics-based optimization model 590 and runs the physics-based optimization model 590 (e.g., to obtain one or more outputs). The profile generation component 514 is capable of determining (e.g., extracting) profile generation data 560 from the physics-based optimization model 590.

In some embodiments, the functions of client device 520, profile generation server 512, and server machine 580 are to be provided by a fewer number of machines. For example, in some embodiments, server machine 580 are integrated into a single machine, while in some other embodiments, server machine 580, and profile generation server 512 are integrated into a single machine. In some embodiments, client device 520 and profile generation server 512 are integrated into a single machine.

In general, functions described in one embodiment as being performed by client device 520, profile generation server 512, and server machine 580 can also be performed on profile generation server 512 in other embodiments, if appropriate. In addition, the functionality attributed to a particular component can be performed by different or multiple components operating together. For example, in some embodiments, the profile generation server 512 generates profiles based on the profile generation data 560. In another example, client device 520 determines the profile generation data 560 based on data received from the physics-based optimization model.

In addition, the functions of a particular component can be performed by different or multiple components operating together. In some embodiments, one or more of the profile generation server 512, or server machine 580 are accessed as a service provided to other systems or devices through appropriate application programming interfaces (API).

In some embodiments, a “user” is represented as a single individual. However, other embodiments of the disclosure encompass a “user” being an entity controlled by a plurality of users and/or an automated source. In some examples, a set of individual users federated as a group of administrators is considered a “user.”

Although embodiments of the disclosure are discussed in terms of determining profile generation data 560 for determining updated profiles or target profiles of a component of a ceramic stack of a substrate support system (e.g., an ESC), in some embodiments, the disclosure can also be generally applied to profile generation and thermal uniformity management for any component in any system and/or manufacturing facility.

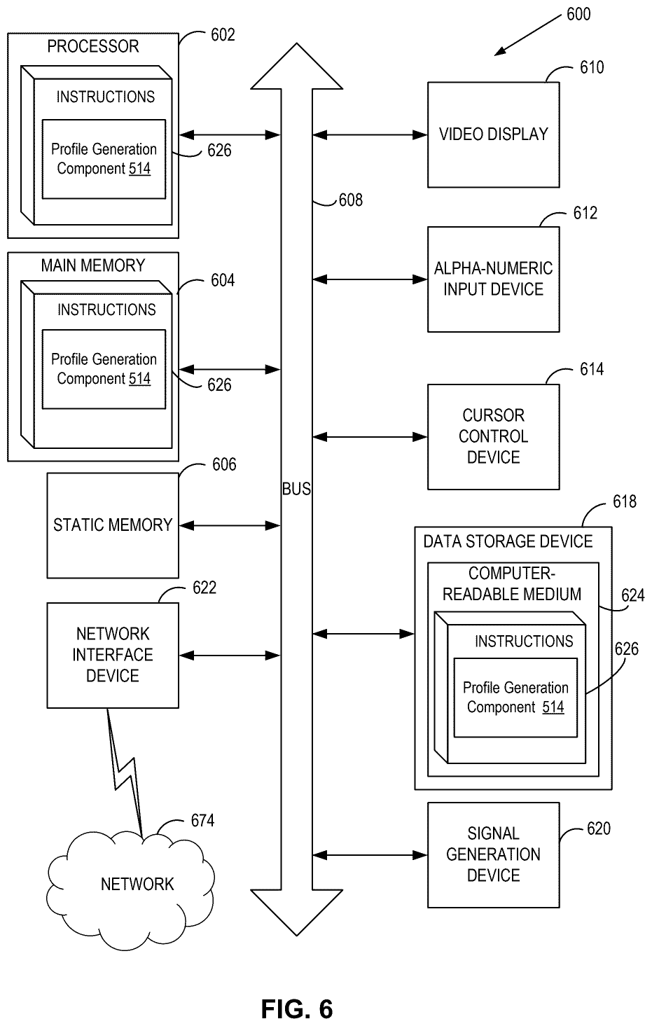

FIG. 6 is a block diagram illustrating a computer system 600, according to certain embodiments. In some embodiments, computer system 600 may be connected (e.g., via a network, such as a Local Area Network (LAN), an intranet, an extranet, or the Internet) to other computer systems. Computer system 600 may operate in the capacity of a server or a client computer in a client-server environment, or as a peer computer in a peer-to-peer or distributed network environment. Computer system 600 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 600 may include a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 618, which may communicate with each other via a bus 608.

Processing device 602 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 600 may further include a network interface device 622 (e.g., coupled to network 674). Computer system 600 also may include a video display unit 610 (e.g., an LCD), an alphanumeric input device 612 (e.g., a keyboard), a cursor control device 614 (e.g., a mouse), and a signal generation device 620.

In some implementations, data storage device 618 may include a non-transitory computer-readable storage medium 624 (e.g., non-transitory machine-readable storage medium) on which may store instructions 626 encoding any one or more of the methods or functions described herein, including instructions encoding profile generation component 514 and for implementing methods described herein.

Instructions 626 may also reside, completely or partially, within volatile memory 604 and/or within processing device 602 during execution thereof by computer system 600, hence, volatile memory 604 and processing device 602 may also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “identifying,” “causing,” “modifying,” “performing,” “partitioning,” “generating,” “determining,” “processing,” “forming,” “applying,” “opening,” “closing,” “measuring,” “calculating,” “changing,” “receiving,” “providing,” “obtaining,” “accessing,” “adding,” “using,” “training,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

What is claimed is:

1. A system, comprising:
a ceramic base; and
a resistive heating trace embedded in the ceramic base, wherein the resistive heating trace comprises:
a plurality of elongated parallel trace segments, wherein each trace segment extends across a major surface of the ceramic base;
a first terminal coupled to a first elongated parallel trace segment of the plurality of elongated parallel trace segments and disposed a first radial distance from a center of the ceramic base; and
a second terminal coupled to a second elongated parallel trace segment of the plurality of elongated parallel trace segments and disposed a second radial distance from the center of the ceramic base.

2. The system of claim 1, further comprising:
a plurality of bridging segments that adjoin adjacent elongated parallel trace segments of the plurality of elongated parallel trace segments, wherein at least one elongated trace segment of the plurality of elongated trace segments or at least one bridging segment of the plurality of bridging segments is disposed between the first terminal and the second terminal.

3. The system of claim 1, wherein the first terminal is disposed on a first horizontal plane and the second terminal is disposed on a second horizontal plane, and wherein the first terminal disposed on the first plane is coupled to the second terminal disposed on the second plane through a via.

4. The system of claim 1, further comprising:
a ceramic stack, wherein the ceramic base is configured as a component of the ceramic stack;
a memory; and
a processing device coupled to the memory, wherein the processing device is to:
determine thermal uniformity data of the ceramic stack;
determine a surface profile of a component of the ceramic stack;
determine an updated surface profile of the component of the ceramic stack based on a physics-based optimization model; and
cause the surface profile of the component of the ceramic stack to be modified based on the updated surface profile.

5. The system of claim 4, wherein the processing device is to determine the thermal uniformity data of the ceramic stack using the physics-based optimization model.

6. The system of claim 4, wherein to determine an updated surface profile of the component of the ceramic stack, the processing device is further to:
determine an optimal bond layout for a bond layer of the ceramic stack, wherein the bond layer is modeled with varying thermal conductivity.

7. The system of claim 4, wherein to determine the thermal uniformity of the ceramic stack, the processing device is further to:
partition a surface of the component of the ceramic stack into a plurality of discrete segments to create a segmented representation of the surface of the component of the ceramic stack for a physics-based optimization model; and
generate a mesh for the segmented surface representing metrology and thermal properties of each discrete segment of the plurality of discrete segments.

8. The system of claim 7, wherein to determine an updated surface profile of the component of the ceramic stack, the processing device is further to:
determine a thickness profile of the component of the ceramic stack based on a determined thickness at each segment of the segmented representation of the surface of the component of the ceramic stack.

9. A method comprising:
identifying a ceramic base of an electrostatic chuck (ESC); and
causing a resistive heating trace to be printed onto the ceramic base of the ESC, wherein the resistive heating trace comprises:
a plurality of elongated parallel trace segments, wherein each trace segment extends across a major surface of the ceramic base;
a first terminal coupled to a first elongated parallel trace segment of the plurality of elongated parallel trace segments and disposed a first radial distance from a center of the ceramic base; and
a second terminal coupled to a second elongated parallel trace segment of the plurality of elongated parallel trace segments and disposed a second radial distance from the center of the ceramic base.

10. The method of claim 9, wherein the resistive heating trace further comprises:
a plurality of bridging segments that adjoin adjacent elongated parallel trace segments of the plurality of elongated parallel trace segments.

11. The method of claim 9, further comprising:
determining thermal uniformity data of a ceramic stack of the ESC;
determining a surface profile of a component of a ceramic stack of the ESC;
determining an updated surface profile of the component of the ceramic stack based on a physics-based optimization model; and
modifying the surface profile of the component of the ceramic stack based on the updated surface profile.

12. The method of claim 11, wherein the determining the thermal uniformity data of the ceramic stack of the ESC is based on a physics-based optimization model.

13. The method of claim 11, wherein modifying the surface profile of the component of the ceramic stack surface based on the updated surface profile comprises:
performing laser material processing of the surface profile of the component of the ceramic stack surface.

14. The method of claim 11, wherein the determining an updated surface profile of the component of the ceramic stack based on a physics-based optimization model comprises:
determining an optimal bond layout, wherein the bond is modeled with varying thermal conductivity.

15. The method of claim 11, wherein the determining the thermal uniformity of the ceramic stack comprises:
partitioning a surface of component of the ceramic stack into a plurality of discrete segments to create a segmented representation of the surface of the component of the ceramic stack for a physics-based optimization model; and
generating a mesh for the segmented surface representing metrology and thermal properties of each discrete segment of the plurality of segments.

16. The method of claim 15, wherein the determining an updated surface profile of the component of the ceramic stack based on a physics-based optimization model comprises:
determining a thickness profile of the component of the ceramic stack based on a determined thickness at each segment of the segmented representation of the component of the ceramic stack.

17. The method of claim 9, wherein at least one elongated trace segment of the plurality of elongated trace segments or at least one bridging segment of the plurality of bridging segments is disposed between the first terminal and the second terminal.

18. An apparatus comprising:
a ceramic base; and
a resistive heating trace embedded in the ceramic base, wherein the resistive heating trace comprises:
a plurality of elongated parallel trace segments;
a first terminal coupled to a first elongated parallel trace segment of the plurality of elongated parallel trace segments;
a second terminal coupled to a second elongated parallel trace segment of the plurality of elongated parallel trace segments; and
a plurality of bridging segments that adjoin adjacent elongated parallel trace segments of the plurality of elongated parallel trace segments, wherein at least one elongated trace segment of the plurality of elongated trace segments or at least one bridging segment of the plurality of bridging segments is disposed between the first terminal and the second terminal.

19. The apparatus of claim 18, wherein:
the first terminal is disposed a first radial distance from a center of the ceramic base; and
the second terminal is disposed a second radial distance from the center of the ceramic base.

20. The apparatus of claim 18, wherein the first terminal is disposed on a first horizontal plane and the second terminal is disposed on a second horizontal plane, and wherein the first terminal disposed on the first plane is coupled to the second terminal disposed on the second plane through a via.
